(19) United States
(12) Patent Application Publication
(10) Pub. No.: US 2017/0298533 A1
(43) Pub. Date: Oct. 19, 2017

(54) METHOD FOR PRODUCING SiC SINGLE CRYSTAL AND APPARATUS FOR PRODUCING SiC SINGLE CRYSTAL

(71) Applicants: NIPPON STEEL & SUMITOMO METAL CORPORATION, Tokyo (JP); TOYOTA JIDOSHA KABUSHIKI KAISHA, Aichi (JP)

(72) Inventors: Kazuhiko KUSUNOKI, Nishinomiya-shi, Hyogo (JP); Kazuhito KAMEI, Kitakyushu-shi, Fukuoka (JP); Kazuaki SEKI, Futtsu-shi, Chiba (JP); Yutaka KISHIDA, Chiba-shi, Chiba (JP); Koji MORIGUCHI, Nishinomiya-shi, Hyogo (JP); Hiroshi KAIDO, Sodegaura-shi, Chiba (JP); Hironori DAIKOKU, Susono-shi, Shizuoka (JP); Masayoshi DOI, Nagoya-shi, Aichi (JP)

(21) Appl. No.: 15/517,187

(22) PCT Filed: Oct. 13, 2015
(86) PCT No.: PCT/JP2015/005169

§ 371 Date: Apr. 6, 2017

(30) Foreign Application Priority Data
Oct. 17, 2014 (JP) 2014-213237

(51) Int. Cl. C30B 19/06; C30B 19/08; C30B 19/04; C30B 29/36; C30B 17/00

(52) U.S. Cl. CPC C30B 19/062; C30B 29/36; C30B 17/00; C30B 19/04; C30B 19/08

(57) ABSTRACT

The provided by the disclosure is a SiC single crystal production method permitting suppression of temperature variation of a Si—C solution even in a case of long-time crystal growth. The SiC single crystal production method includes: a preparation step of preparing a production apparatus including a crucible, a seed shaft, and an internal lid; a formation step of heating the material in the crucible to form the Si—C solution; a growth step of bringing the seed crystal into contact with the Si—C solution to produce the Si—C single crystal on the seed crystal; an internal lid adjustment step of vertically moving one of the internal lid and the crucible relative to the other during the growth step to keep an amount of variation in vertical distance between the internal lid and the Si—C solution within a first reference range.

### TECHNICAL FIELD

The present invention relates to a method for producing a single crystal and an apparatus for producing a single crystal. In particular, it relates to a method for producing a SiC single crystal and an apparatus for producing a SiC single crystal.

### BACKGROUND ART

A solution growth process is an example of a method for producing a SiC single crystal. In the solution growth process, a seed crystal attached to the bottom edge of a seed shaft is brought into contact with a Si—C solution contained in a crucible, whereby a SiC single crystal grows on the seed crystal. The Si—C solution means a solution in which carbon (C) is dissolved in a melt of Si or a Si alloy.

In the solution growth process, the portion of the SiC solution immediately below and in vicinity to the seed crystal (the portion hereinafter referred to simply as vicinity portion) is cooled to below the temperature of the other portion. Then, SiC in the vicinity portion is supersaturated, thereby promoting the growth of the SiC single crystal. Thus, during a crystal growth, the vicinity portion is supersaturated.

However, when the temperature of the portion of the SiC solution other than the vicinity portion (the other portion hereinafter referred to as peripheral portion) varies, spontaneous nucleation occurs in the peripheral portion, and SiC polycrystallization is likely to occur. The formed SiC polycrystals move to the seed crystal along with the flow of the Si—C solution. If many SiC polycrystals stick to the SiC single crystal growing on the seed crystal, it will hinder the growth of the SiC single crystal.

Techniques to suppress the temperature variation of the peripheral portion are disclosed in Japanese Patent Application Publication No. 2004-323247 (Patent Literature 1), Japanese Patent Application Publication No. 2006-131433 (Patent Literature 2) and Japanese Patent Application Publication No. 2013-1619 (Patent Literature 3).

In the production method disclosed in Patent Literature 1, a heat insulating member such as a graphite cover is disposed above the liquid surface of the solution to suppress heat radiation from the liquid surface of the Si—C solution. In the production method disclosed in Patent Literature 2, also, a heat insulating member is disposed in a free space above the crucible.

In the production method disclosed in Patent Literature 3, the crucible includes an internal lid. The internal lid is disposed inside the crucible, above the liquid surface of the Si—C solution, and is fixed to the inner surface of the crucible. The internal lid has a first through hole which a seed shaft passes through. According to Patent Literature 3, the internal lid keeps the heat in the space between the internal lid and the liquid surface of the Si—C solution. Thereby, temperature variation of the peripheral portion can be suppressed.

### CITATION LIST

### Patent Literature

Patent Literature 1: Japanese Patent Application Publication No. 2004-323247
Patent Literature 2: Japanese Patent Application Publication No. 2006-131433
Patent Literature 3: Japanese Patent Application Publication No. 2013-1619

### SUMMARY OF INVENTION

### Technical Problem

Recently, production of an elongated SiC bulk single crystal by the solution growth process has been attempted. A long crystal growth time is necessary to produce an elongated SiC bulk single crystal. During such a long-time crystal growth, the liquid surface of the Si—C solution becomes lower as the SiC single crystal is growing. In this case, the distance between such a heat insulating member or intermediate lid as those disclosed in the Patent Literatures 1 to 3 and the liquid surface of the Si—C solution becomes greater, and the heat retaining effect of the heat insulating member or intermediate lid becomes weak. Accordingly, as the crystal growth time becomes longer, the temperature of the peripheral portion becomes more variable, and SiC polycrystallization becomes more likely to occur. Further, the temperature of the vicinity portion may drop to below a set temperature.

An object of the present invention is to provide a SiC single crystal production method and a SiC single crystal production apparatus that can suppress temperature variation of a Si—C solution even during a long-time crystal growth.

### Solution to Problem

A SiC single crystal production method according to an embodiment comprises: a preparation step of preparing a production apparatus comprising a crucible containing material for Si—C solution, a seed shaft including a bottom edge which a seed crystal is attached to, and an internal lid having, in a center, a through hole which the seed shaft passes through and capable of being located inside the crucible; a formation step of heating the material in the crucible to form the Si—C solution; a growth step of bringing the seed crystal into contact with the Si—C solution to produce the SiC single crystal on the seed crystal; and an internal lid adjustment step of vertically moving one of the internal lid and the crucible relative to the other during the growth step to keep an amount of variation in distance between the internal lid and the Si—C solution within a first reference range.

### Advantageous Effects of Invention

In the SiC single crystal production method according to the embodiment, it is possible to suppress temperature variation of the Si—C solution even during a long-time crystal growth.

### BRIEF DESCRIPTION OF DRAWINGS

FIG. 1 is a schematic configuration diagram of a SiC single crystal production apparatus according to a first embodiment.

FIG. 2 is a diagram illustrating lowering of the liquid surface of a Si—C solution during a growth of a SiC single crystal.

FIG. 3 is a diagram illustrating a step to be carried out subsequent to the occurrence illustrated in FIG. 2.

FIG. 4 is a diagram illustrating a step alternative to the step illustrated in FIG. 3 to be carried out subsequent to the occurrence illustrated in FIG. 2.

FIG. 5 is a schematic configuration diagram of a SiC single crystal production apparatus according to a second embodiment.

FIG. 6 is a diagram illustrating a production method carried out by use of the production apparatus shown in FIG. 5.

FIG. 7 is a schematic configuration diagram of a production apparatus used to produce a comparative example.

### DESCRIPTION OF EMBODIMENTS

Some embodiments of the present invention will hereinafter be described with reference to the drawings. In the drawings, the same parts or the counterparts are provided with the same reference symbols, and descriptions of these parts will not be repeated.

A SiC single crystal production method according to an embodiment comprises: a preparation step of preparing a production apparatus comprising a crucible containing material for Si—C solution, a seed shaft including a bottom edge which a seed crystal is attached to, and an intermediate lid having, in the center, a through hole which the seed shaft passes through, the internal lid capable of being located inside the crucible; a formation step of heating the material in the crucible to form a Si—C solution; a growth step of bringing the seed crystal into contact with the Si—C solution to produce a SiC single crystal on the seed crystal; and an internal lid adjustment step of vertically moving one of the intermediate lid and the crucible relative to the other during the growth step such that the amount of variation in the vertical distance between the internal lid and the Si—C solution is within a first reference range.

In the SiC single crystal production method according to the embodiment, during the growth step, one of the intermediate lid and the crucible is lifted or lowered relative to the other to keep the distance between the intermediate lid and the Si—C solution constant. Thereby, the heat retaining effect of the intermediate lid can be maintained, and it is possible to suppress temperature variation of the vicinity portion and temperature variation of the peripheral portion. Accordingly, a SiC single crystal easily grows.

In the intermediate lid adjustment step, the amount of variation in the vertical distance between the intermediate lid and the Si—C solution is adjusted, for example, based on the amount of change in the vertical position of the liquid surface of the Si—C solution per unit time during the growth step.

In this case, it is easy to adjust the amount of variation in the vertical distance between the intermediate lid and the Si—C solution.

It is preferred that the production apparatus further comprises a high-frequency heating coil disposed around the crucible, and it is preferred that the production method further comprises a coil adjustment step of vertically moving one of the high-frequency heating coil and the crucible relative to the other such that the amount of variation in positions of the high-frequency heating coil and the Si—C solution relative to each other is within a second reference range.

In this case, it is possible to suppress variation in the capability of the coil to heat the Si—C solution during the growth step. Accordingly, the temperature of the Si—C solution is kept constant more easily.

In the coil adjustment step, the amount of variation in the relative vertical positions of the high-frequency heating coil and the Si—C solution is adjusted, for example, based on the amount of change in the vertical position of the Si—C solution per unit time during the growth step.

Thereby, it is easy to adjust the amount of variation in the relative vertical positions of the high-frequency heating coil and the Si—C solution.

The production apparatus according to the present embodiment produces a SiC single crystal by the solution growth process. The production apparatus comprises a chamber, a base, a seed shaft, and an internal lid. The chamber is capable of housing a crucible capable of containing a Si—C solution. The base is capable of supporting the crucible. The seed shaft includes a bottom edge which a seed crystal is attachable to. The internal lid includes, in the center, a through hole which the seed shaft passes through, and is capable of being located inside the crucible, above the liquid surface of the Si—C solution. One of the base and the internal lid is vertically movable relative to the other.

In the production apparatus according to the present embodiment, one of the internal lid and the base is movable up and down relative to the other. This allows for adjustment of the amount of variation in the vertical distance between the internal lid and the Si—C solution in the crucible placed on the base.

Preferably, the production apparatus further comprises a high-frequency heating coil. The crucible is capable of being located inside the high-frequency heating coil. One of the base and the high-frequency heating coil is vertically movable relative to the other.

In this case, it is possible to adjust the amount of variation in the relative vertical positions of the high-frequency heating coil and the Si—C solution in the crucible placed on the base.

Preferably, the production apparatus further comprises an internal lid lifting mechanism. The internal lid lifting mechanism lifts and lowers the internal lid separately from the seed shaft and the crucible.

Preferably, the production apparatus further comprises a crucible lifting mechanism. The crucible lifting mechanism lifts and lowers the base, on which the crucible is placed, separately from the internal lid.

Preferably, the production apparatus further comprises a coil lifting mechanism that lifts and lowers the high-frequency heating coil.

A SiC single crystal production method according to the present embodiment and a production apparatus implementing the production method will hereinafter be described.

### First Embodiment

### [Overall Structure of SiC Single Crystal Production Apparatus 100]

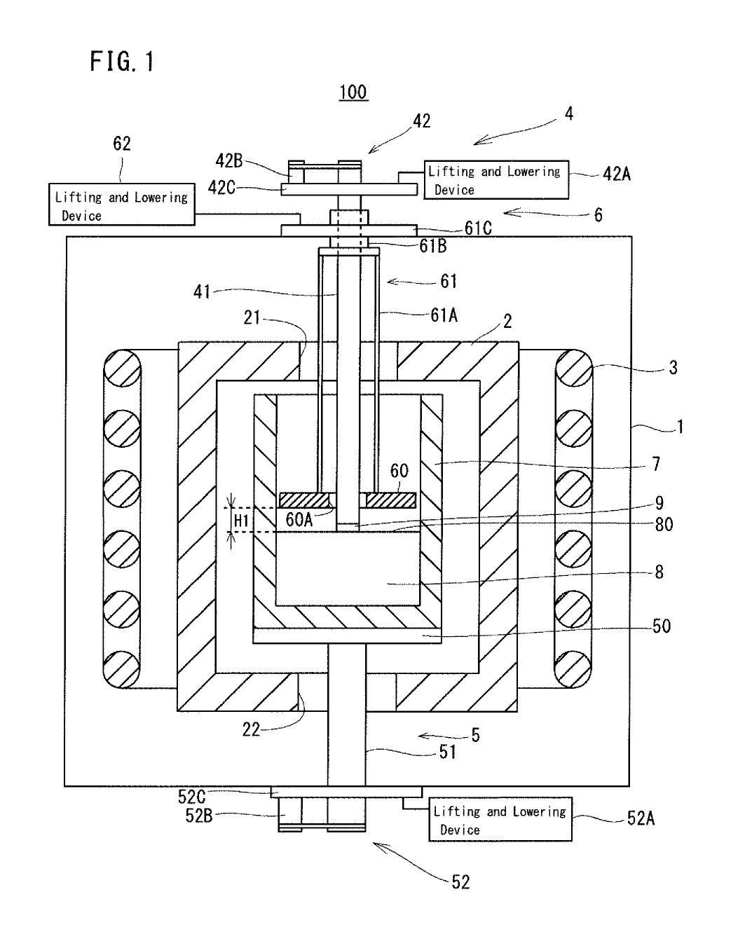

FIG. 1 is a schematic configuration diagram of a SiC single crystal production apparatus 100 according to a first embodiment. As shown in FIG. 1, the production apparatus 100 comprises a chamber 1, a heat insulator 2, a high-frequency heating coil 3, a seed shaft drive mechanism 4, a crucible drive mechanism 5, and an intermediate lid drive mechanism 6.

The chamber 1 is a housing that houses the heat insulator 2, the high-frequency heating coil 3, and a seed shaft 41 of the seed shaft drive mechanism 4. The chamber 1 is further capable of housing a crucible 7. When a SiC single crystal is produced, the chamber 1 is cooled with water.

The crucible 7 is located inside the heat insulator 2, which is like a housing. The crucible 7 is an open-topped container. The crucible 7 contains a Si—C solution 8. The Si—C solution 8 is produced by melting material for Si—C solution by heat. The material may contain only Si, or alternatively may contain not only Si but also other metal elements. The metal elements that may be contained in the material for Si—C solution are, for example, titanium (Ti), manganese (Mn), chromium (Cr), cobalt (Co), vanadium (V), iron (Fe) and the like.

The material of the crucible 7 is graphite, for example. When the crucible 7 is made of graphite, the crucible 7 itself serves as a supply source of carbon for the Si—C solution 8. The crucible 7 may be made of a material other than graphite. For example, the crucible 7 may be made of ceramics or high melting point metal. When the crucible 7 cannot be used as a supply source of carbon, the material for Si—C solution 8 contains C. Also, when the crucible 7 is made of a material other than graphite, the inner surface of the crucible 7 may be coated with graphite.

The high-frequency heating coil 3 is disposed to surround the crucible 7. In other words, the crucible 7 is located inside the high-frequency coil 3. The high-frequency heating coil 3 is arranged coaxially with the seed shaft 41 and a shaft 51. The high-frequency heating coil 3 heats the crucible 7 inductively and melts the material in the crucible 7, whereby the Si—C solution 8 is produced. The high-frequency heating coil 3 also maintains the Si—C solution 8 at a crystal growth temperature.

The heat insulator 2 is like a housing, and has a side wall, a top lid and a bottom lid. The side wall of the heat insulator 2 is disposed between the high-frequency heating coil 3 and the crucible 7. The side wall of the heat insulator 2 is disposed around the crucible 7. The top lid of the heat insulator 2 is disposed above the crucible 7. The top lid has a through hole 21 which the seed shaft 41 passes through. The bottom lid of the heat insulator 2 is disposed below the crucible 7. The bottom lid has a through hole 22 which the shaft 51 passes through. The heat insulator 2 surrounds the crucible 7 entirely. The heat insulator 2 includes a conventional heat insulating material. The heat insulating material is a shaped heat insulating member of a fiber or non-fiber material.

### [Seed Shaft Drive Mechanism 4]

The seed shaft drive mechanism 4 includes a seed shaft 41 and a drive unit 42. The seed shaft 41 is arranged coaxially with the shaft 51. The bottom edge of the seed shaft 41 is located in the chamber 1, and the top edge of the seed shaft 41 is located above the chamber 1. Thus, the seed shaft 41 passes through the chamber 1.

The seed shaft 41 is rotatable around the central axis thereof and also movable up and down. The drive unit 42 includes a lifting and lowering device 42A, a rotating device 42B, and a support 42C. The support 42C is located above the chamber 1. The support 42C has a hole which the seed shaft 41 passes through. The support 42C supports the seed shaft 41 and the rotating device 42B.

The rotating device 42B permits the seed shaft 41 to rotate around the central axis of the seed shaft 41. Thereby, the seed crystal 9 attached to the bottom edge of the seed shaft 41 rotates.

The lifting and lowering device 42A lifts and lowers the seed shaft 41. Specifically, the lifting and lowering device 42A is connected to the support 42C, and lifts and lowers the support 42C. Accordingly, the lifting and lowering device 42A lifts and lowers the seed shaft 41A via the support 42C.

A seed crystal 9 is attachable to the bottom edge of the seed shaft 41. The seed crystal 9 is shaped like a plate. The seed crystal is preferably a SiC single crystal. During production by the solution growth process, a SiC single crystal is formed and grown on the surface (crystal growth surface) of the seed crystal. When a SiC single crystal of the 4H polytype is to be produced, the SiC seed crystal 9 is preferably a single crystal of the 4H polytype. More desirably, the surface (crystal growth surface) of the SiC seed crystal 9 is the (0001) plane or a plane that is 8° or less off-axis from the (0001) plane. In such a case, a SiC single crystal is grown stably.

When a SiC single crystal is to be produced, the seed shaft 41 is lowered to bring the SiC seed crystal 9 into contact with the SiC solution 8 (to soak the SiC seed crystal 9 in the Si—C solution) as illustrated in FIG. 1. Then, the Si—C solution 8 is maintained at the crystal growth temperature. The crystal growth temperature is the temperature of the Si—C solution 8 at which a SiC single crystal is grown, and the crystal growth temperature depends on the composition of the Si—C solution 8. The crystal growth temperature is typically 1600 to 2000° C.

### [Crucible Drive Mechanism 5]

The crucible drive mechanism 5 includes a base 50, a shaft 51, and a drive unit 52. The base 50 is disposed in the heat insulator 2, which is like a housing. The crucible 7 is placed on the base 50.

The shaft 51 is fixed to the bottom surface of the base 50 and is arranged coaxially with the seed shaft 41. The shaft 51 passes through the bottom surface of the heat insulator 2 and the bottom surface of the chamber 1, and the bottom edge of the shaft 51 is located below the chamber 1.

The drive unit 52 includes a lifting and lowering device 52A, a rotating device 52B, and a support 52C. The support 52C is located below the chamber 1. The support 52C has a hole which the shaft 51 passes through. The support 52C supports the shaft 51 and the rotating device 52B. The rotating device 52B permits the shaft 51 to rotate around the central axis of the shaft 51. The lifting and lowering device 52A is connected to the support 52C, and lifts and lowers the support 42C. Accordingly, the lifting and lowering unit 52A lifts and lowers the base 50 via the support 52C.

### [Internal Lid Drive Mechanism 6]

The internal lid drive mechanism 6 includes an internal lid 60, a support unit 61, and a lifting and lowering device 62. The internal lid 60 is shaped like a disk, and has, in the center, a through hole 60A which the seed shaft 41, passes thorough. As shown in FIG. 1, the internal lid 60 is located above the liquid surface of the Si—C solution 8, and keeps the heat in the space between the internal lid 60 and the liquid surface 80 of the Si—C solution 8. Thereby, the vicinity portion of the Si—C solution 8 immediately below the seed crystal is easily maintained at constant temperature uniformly and also, the peripheral portion other than the vicinity portion is easily maintained at constant temperature uniformly. In order to secure this effect, the bottom surface of the internal lid 60 is preferably flat. In this case, the vertical distance H1 between the bottom surface of the internal lid 60 and the liquid surface 80 is substantially constant regardless of the position, and the vicinity portion and the peripheral portion are easily maintained at constant temperature uniformly. A space is made between the side surface of the internal lid 60 and the inner surface of the crucible 7 so as to avoid friction. The space is preferably as small as possible. When the space is small, the area of the vicinity portion and the peripheral portion opposed to the internal lid 60 is large. In this case, accordingly, the vicinity portion and the peripheral portion are maintained at constant temperature more uniformly. Specifically, it is preferred that the space is not more than 5 mm. More desirably, the space is not more than 2 mm.

The support unit 61 includes a cylindrical or rod-like connector 61A, a shaft member 61B connected to the top edge of the connector 61A, and a support 61C. The connector 61A extends in the height direction of the production apparatus 100. The bottom edge of the connector 61A is fixed to the upper surface of the internal lid 60. The shaft member 61B is cylindrical, and the seed shaft 41 is inserted in the shaft member 61B. The shaft member 61B passes through the upper wall of the chamber 1, and the top edge of the shaft member 61B is located above the chamber 1. The bottom edge of the shaft member 61B is fixed to the top edge of the connector 61A. The support 61C supports the internal lid 60 via the shaft member 61B and the connector 61A. The support 61C has a through hole which the shaft member 61B passes through. The lifting and lowering device 62 lifts and lowers the internal lid 60 together with the support 61C.

### [SiC Single Crystal Production Method]

The production apparatus 100 is capable of lifting and lowering the internal lid 60 separately from the seed shaft 41 and the crucible 7. The production apparatus 100 is further capable of lifting and lowering the base 50, which supports the crucible 7, separately from the internal lid 7. Accordingly, the production apparatus 100 is capable of vertically moving one of the internal lid 60 and the crucible 7 placed on the base 50 relative to the other. Therefore, even when the liquid surface 80 of the Si—C solution 8 becomes lower along with the advance of a crystal growth, the amount of variation ΔH1 in the vertical distance H1 between the internal lid 60 and the liquid surface 80 (i.e., in the relative vertical positions of the internal lid 60 and the liquid surface 80) can be kept within a reference range Ref1. A SiC single crystal production method will hereinafter be described.

A SiC single crystal production method comprises a preparation step, a formation step, a growth step, and an internal lid adjustment step.

### [Preparation Step]

In the preparation step, the above-descried production apparatus 100 is prepared. Then, a seed crystal 9 is attached to the bottom edge of the seed shaft 41. The crucible 7 containing material for Si—C solution 8 is put in the chamber 1 and placed on the base 50. At this stage, the intermediate lid 60 may be positioned inside the crucible 7 or may be positioned above the crucible 7.

### [Formation Step]

Next, a Si—C solution 8 is formed. In this step, first, the chamber 1 is filled with an inert gas. Thereafter, the material for Si—C solution 8 in the crucible 7 is heated to above the melting point of the material by the high-frequency heating coil 3. In a case where the crucible 7 is made of graphite, heating of the crucible 7 causes dissolving of carbon out from the crucible 7 into the melt of the material, and the Si—C solution 8 is formed. The dissolving of carbon out from the crucible 7 into the Si—C solution 8 causes the carbon concentration in the Si—C solution 8 to come close to the saturation concentration.

### [Growth Step]

Next, the drive unit 42 lowers the seed shaft 41 to bring the seed shaft 9 into contact with the Si—C solution 8. After the seed shaft 9 comes into contact with the Si—C solution 8, the seed shaft 41 is slightly lifted, and a meniscus is formed between the seed shaft 9 and the liquid surface 80.

After the meniscus formation, the Si—C solution 8 is maintained at the crystal growth temperature by the high-frequency heating coil 3. Further, the vicinity portion of the Si—C solution 8 around the seed crystal 9 is supercooled, whereby SiC in the vicinity portion is supersaturated.

There is no special limit to the way of supercooling the vicinity portion of the Si—C solution around the seed crystal 9. For example, the high-frequency heating coil 3 is controlled to make the temperature of the vicinity portion around the seed crystal 9 lower than the temperature of the other portion. Alternatively, the vicinity portion may be cooled by a coolant. Specifically, a coolant is circulated inside the seed shaft 41. The coolant is, for example, an inert gas such as helium (He), argon (Ar) or the like. The coolant circulated in the seed shaft 41 cools the seed crystal 9. The cooling of the seed crystal 9 leads to cooling of the vicinity portion.

While SiC in the vicinity portion is kept supercooled, the seed crystal 9 and the Si—C solution 8 (crucible 7) are rotated. The seed shaft 41 is rotated by the rotating device 42B, whereby the seed crystal 9 is rotated. The crucible 7 is rotated by the rotating device 52B. The rotational direction of the seed crystal 9 may be opposite to or the same as the rotational direction of the crucible 7. The rotational speed of the seed crystal 9 and the rotational speed of the crucible 7 may be constant or may be variable. In the meantime, a SiC single crystal grows on the bottom surface (crystal growth surface) of the seed crystal 9 in contact with the Si—C solution 8. It is to be noted that the seed shaft 41 need not be rotated.

Before the growth of SiC single crystal is started, the internal lid 60 is lowered by the lifting and lowering device 62. Thereby, the vertical distance between the internal lid 60 and the liquid surface 80 is set to H1. After the internal lid 60 is set in a predetermined position, the crystal growth is started.

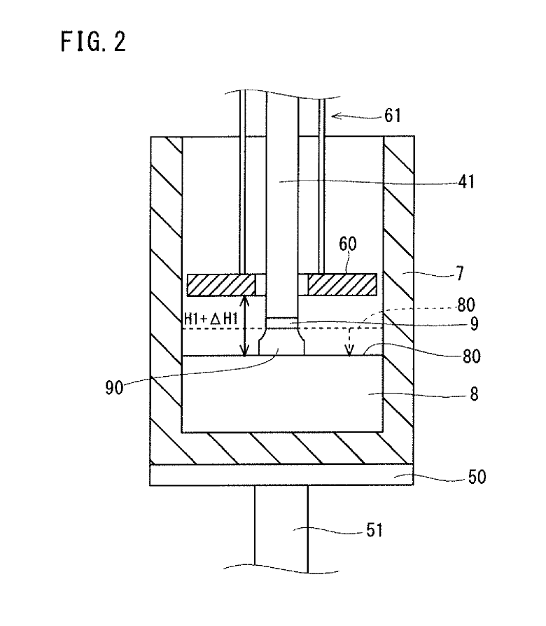

Lengthening of the crystal growth time allows for thickening of the SiC single crystal grown on the seed crystal 9. However, as the SiC single crystal is growing, the liquid surface 80 of the Si—C solution 8 becomes lower. Specifically, in a case where the vertical distance between the internal lid 60 and the liquid surface 80 at the start of the crystal growth is set to H1, as shown in FIG. 2, the liquid surface 80 becomes lower as the SiC single crystal 90 is growing, and the distance H1 increases to H1+ΔH1.

If the amount of variation ΔH1 exceeds the reference value Ref1, the distance between the seed crystal 9 and the liquid surface 80 will be too large. Then, the heat retaining effect of the internal lid 60 will decrease. Thereby, the temperature of the peripheral portion of the Si—C solution 8 will be uneven. Further, the temperature of the vicinity portion of the Si—C solution 8 will be uneven, and the degree of supersaturation of SiC will be too high. Then, inclusions will be formed readily. Accordingly, the quality of the SiC single crystal will decrease. In the first embodiment, therefore, the internal lid adjustment step is carried out during the growth step to increase the heat retaining effect of the internal lid 60.

### [Internal Lid Adjustment Step]

In the internal lid adjustment step, one of the internal lid 60 and the crucible 7 is vertically moved relative to the other to keep the amount of variation ΔH1 not more than the reference value Ref1.

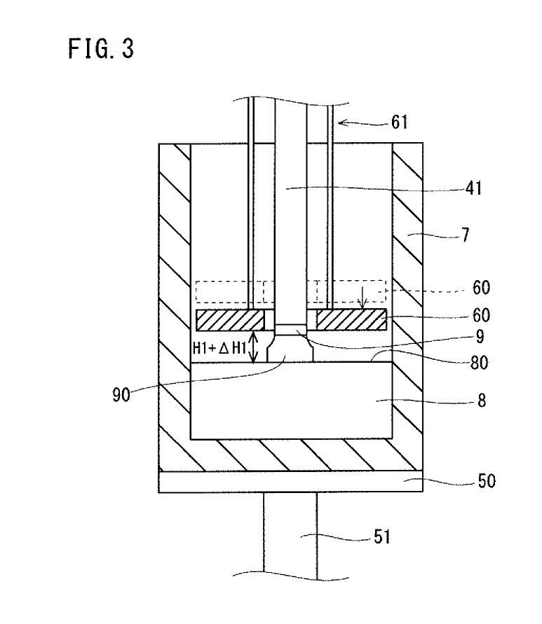

Specifically, as shown in FIG. 3, while the vertical position of the crucible 7 (base 50) is fixed, the internal lid 60 is lowered to keep the amount of variation ΔH1 within the reference range Ref1. As mentioned above, in the production apparatus 100, the internal lid driving mechanism 6 permits the internal lid 60 to move up and down separately from the crucible 7. Accordingly, the internal lid 60 can be lowered while the crucible 7 is kept in a fixed vertical position.

FIG. 3 shows a case where the amount of variation ΔH1 is adjusted by lowering the internal lid 60 while keeping the crucible 7 in a fixed vertical position. However, it is also possible to keep the amount of variation ΔH1 within the reference range Ref1 by lifting the crucible 7 (base 50) while keeping the internal lid 60 in a fixed vertical position.

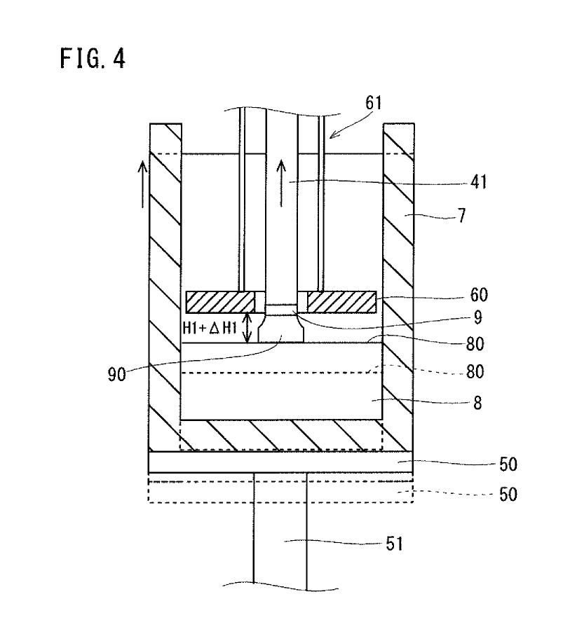

Specifically, as shown in FIGS. 1 and 4, the shaft 51 and the base 50 are lifted by the lifting and lowering device 52A while the internal lid 60 is kept in a fixed vertical position. Thus, the amount of variation ΔH1 can be kept within the reference range Ref1 by upward movement of the crucible 7.

As thus far described, in the SiC single crystal production method according to the first embodiment, one of the internal lid 60 and the crucible 7 is vertically moved relative to the other to keep the amount of variation ΔH1 within the reference range Ref1. Accordingly, even if the crystal growth time is long, for example, 30 hours or more, 40 hours or more, or 50 hours or more, the heat retaining effect of the internal lid 60 can be maintained. This inhibits temperature variation of the vicinity portion of the Si—C solution 8 and temperature variation of the peripheral portion of the Si—C solution 8, thereby leading to inhibition of formation of SiC polycrystals and inclusions. Consequently, a high-quality SiC single crystal can be produced.

There are various ways of detecting the amount of variation in the vertical position of the liquid surface 80 of the Si—C solution 8. For example, before the growth step, the vertical positions of the liquid surface 80 at various elapsed times from the start of a crystal growth are prospectively evaluated (sample step).

Specifically, the same material as the above-described material for SiC single crystal 90 is put in the crucible 7, and a sample Si—C solution 8 is formed in the formation step. Thereafter, the crucible 7 is let cool. After the cooling, the crucible 7 is taken out of the chamber 1, and the vertical position of the liquid surface 80 of the sample Si—C solution 8 (the sample Si—C solution 8 is solidified at this moment because it is in room temperature) in the crucible 7 is measured. Further, another crucible 7 containing the same material is prepared, and a SiC crystal is grown at the above-described growth conditions (crystal growth speed, crystal growth time and the like) for the SiC single crystal 90. After the growth, the vertical position of the liquid surface 80 in the crucible 7 is measured. Based on the crystal growth time, the vertical position of the liquid surface 80 at the start of the growth step and the vertical position of the liquid surface 80 at the end of the growth step, the amount of variation in the vertical position of the liquid surface 80 per unit time during the crystal growth is calculated.

The way of evaluating the vertical position of the liquid surface 80 at the start of the growth of the sample SiC single crystal is not limited to the above-described method. For example, there is another method as follows. First, the sample SiC single crystal is grown in the above-described manner. Subsequently, the sample Si—C solution 8 is solidified. Then, from the mark of the sample Si—C solution 8 appearing on the inner surface of the crucible 7, the vertical position of the liquid surface 80 at the start of the growth is determined.

Based on the thus calculated amount of variation in the vertical position of the liquid surface 80 per unit time, the amount of movement of one of the internal lid 60 and the crucible 70 relative to the other is determined. Based on the determined amount of relative movement, the amount of variation ΔH1 in the distance between the liquid surface 80 and the internal lid 60 during the growth step is kept within the reference range Ref1.

The way of evaluating the vertical position of the liquid surface 80 is not limited to the above-described method. For example, the vertical position of the liquid surface 80 may be evaluated by simulation.

For evaluation of the vertical positions of the liquid surface 80 at various elapsed times, it is not necessarily required to calculate the amount of variation in the vertical position of the liquid surface 80 of the sample Si—C solution per unit time. For example, the following method is possible. The vertical positions of the liquid surface 80 of the sample Si—C solution at the start of the growth of the sample SiC crystal and at a certain elapsed time are measured, and based on the measurement results, the vertical positions of the liquid crystal 80 at various elapsed times are evaluated.

It is also possible to measure the vertical positions of the liquid surface 80 during an actual growth step of the SiC single crystal 90. As a way of measuring the vertical positions of the liquid surface 80, for example, a non-contact optical detection technique, an electrical detection technique by bringing a jig (not shown in the drawings) into contact with the liquid surface 80, or other technique may be employed. The non-contact optical detection technique is based on the principle of triangulation. The position of the liquid surface 80 is determined with the liquid surface 80 considered as a direct reflector. According to the electrical detection technique, for example, a jig made of a conductive material electrically insulated from the chamber 1 (for example, a graphite rod) is lowered until it comes into contact with the liquid surface 80. In this regard, by applying a voltage to the jig, it is possible to cause electrical conduction by contact of the jig with the liquid surface 80. For example, when a pair of jigs is provided, electrical conduction between the pair of jigs is caused. Alternatively, electrical conduction may be caused between one jig and the seed shaft 41. Based on the position of the jig when electrical conduction is caused, the position of the liquid surface 80 is detected. After the detection of the position of the liquid surface 80, the jig is lifted and separated from the liquid surface 80. After the elapse of a predetermined period of time, the jig is lowered again for detection of the position of the liquid surface 80. The jig to be lowered at this moment is preferably different from the jig used for the previous detection. This is because the jig used for the previous detection may have the Si—C solution 8 in a solidified form attached thereto.

In this way, the vertical positions of the liquid surface 80 during the growth step can be detected. It is, therefore, possible to keep the amount of variation ΔH1 not more than the reference value Ref1 by moving one of the intermediate lid 60 and the crucible 7 relative to the other based on the detected position of the liquid surface 80.

### Second Embodiment

In the first embodiment, in order to suppress temperature variation in the vicinity portion and temperature variation in the peripheral portion of the Si—C solution 8, the amount of variation ΔH1 in the distance between the internal lid 60 and the liquid surface 80 is kept not more than the reference value Ref1.

Meanwhile, when the liquid surface 80 becomes lower, the positional relationship between the liquid surface 80 and the high-frequency heating coil 3 (the relative vertical positions of the liquid surface 80 and the high-frequency heating coil 3 to each other) changes. In this case, the condition of the high-frequency heating coil 3 to heat the Si—C solution 8 is changeable. It is, therefore, preferred that the positional relationship between the liquid surface 80 and the high-frequency heating coil 3 is kept the same since the start of a crystal growth.

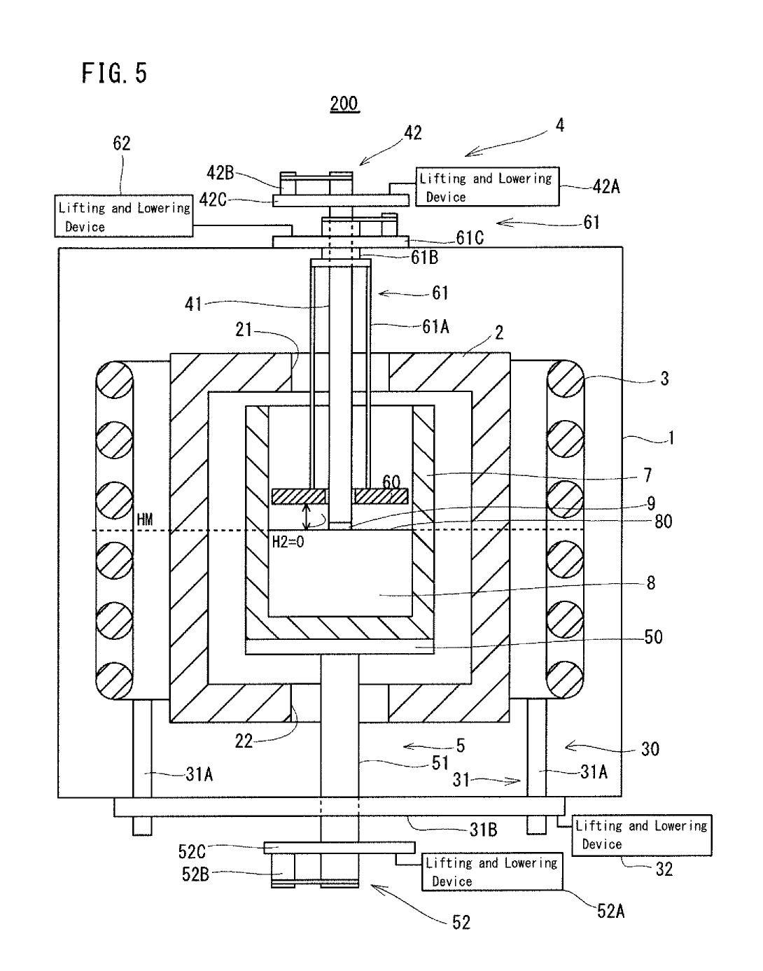

FIG. 5 is a schematic configuration diagram of a SiC single crystal production apparatus 200 according to a second embodiment. As shown in FIG. 5, the production apparatus 200 further comprises a lifting mechanism 30 for the high-frequency heating coil 3 as compared with the production apparatus 100. The production apparatus 200 has no other differences in structure from the production apparatus 100. The lifting mechanism 30 lifts and lowers the high-frequency heating coil 3. The lifting mechanism 30 includes a support unit 31 and a lifting and lowering device 32. The support unit 31 includes a connector 31A and a support 31B. In this embodiment, the connector 31A is a pair of rods, and the upper edge thereof is fixed to the bottom edge of the high-frequency heating coil 3. The bottom edge of the connector 31A is fixed to the support 31B. The support 31B is disposed below the chamber 1 and is connected to the lifting and lowering device 32. The lifting and lowering device 32 lifts and lowers the high-frequency heating coil 3 via the support unit 31.

The heating performance of the high-frequency heating coil 3 may vary from portion to portion in the vertical direction. Typically, the vertically central point HM of the high-frequency heating coil 3 gives the best heating performance. It is, therefore, preferred that the relative vertical positions of the high-frequency heating coil 3 and the liquid surface 80 are kept the same during the growth step.

As shown in FIG. 5, given that the vertical position of the liquid surface 80 at the start of the growth step is the same as that of the vertically central point HM of the high-frequency heating coil 3. In this case, the vertical distance H2 between the vertically central point HM and the liquid surface 80 at this moment is zero.

In the second embodiment, the high-frequency heating coil 3 is lifted and lowered during the growth step to keep the amount of variation ΔH2 in the vertical distance between the vertically central point HM and the liquid surface 80 not more than a reference value Ref2 (coil adjustment step). The amount of variation ΔH2 corresponds to the amount of variation in the relative vertical positions of the high-frequency heating coil 3 and the Si—C solution 8. Therefore, the amount of variation in the relative positions of the high-frequency heating coil 3 and the liquid surface 80 can be kept not more than the reference value Ref2. Accordingly, even as time passes during a crystal growth, the performance of the high-frequency heating coil 3 in heating the Si—C solution 8 is unlikely to change, and temperature variation of the Si—C solution 8 can be suppressed easily.

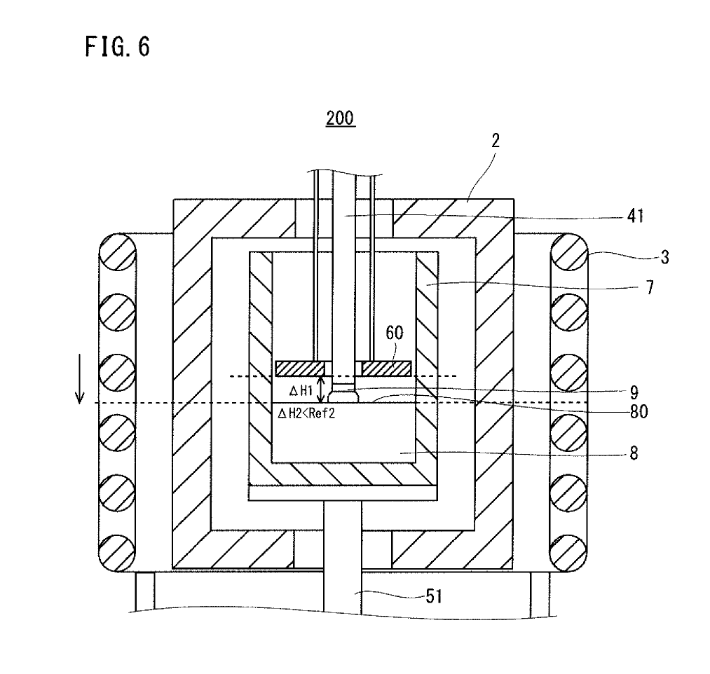

Specifically, as shown in FIG. 6, it is assumed that the liquid surface 80 is lowered from the position indicated by the broken line to the position indicated by the solid line as time passes during a crystal growth. In this case, the high-frequency heating coil 3 is lowered by the lifting and lowering device 32 as time passes during the crystal growth such that the amount of variation ΔH2 can be kept not more than the reference value Ref2.

In the second embodiment also, as with the first embodiment, one of the internal lid 60 and the crucible 7 is moved relative to the other such that the amount of variation ΔH1 is kept not more than the reference value Ref1.

In the above embodiments, the reference values Ref1 and Ref2 are set appropriately based on the historical production performance and the like.

In the above embodiments, the internal lid lifting mechanism 6 need not have the above-described structure. There is no specific limit to the structure of the internal lid lifting mechanism 6 as long as the internal lid lifting mechanism 6 is capable of lifting and lowering the internal lid 60. In the same way, there is no specific limit to the structure of the crucible lifting mechanism 6 as long as the crucible lifting mechanism 6 is capable of lifting and lowering the crucible 7. Also, there is no specific limit to the structure of the high-frequency heating coil lifting mechanism 30 as long as the high-frequency heating coil lifting mechanism 30 is capable of lifting and lowering the high frequency heating coil 30.

The SiC production apparatuses according to the above-described embodiments are capable of lifting and lowering the internal lid and also lifting and lowering the crucible (base). However, the production apparatuses may be capable of lifting and lowering only one of the internal lid and the crucible (base). For example, the production apparatuses may be capable of lifting and lowering the internal lid and incapable of lifting and lowering the crucible. In this case, since the vertical position of the crucible is fixed, the amount of variation ΔH1 is controlled by lifting and lowering the internal lid. Alternatively, the production apparatuses may be capable of lifting and lowering the crucible and incapable of lifting and lowering the internal lid. In this case, since the vertical position of the internal lid is fixed, the amount of variation ΔH1 is controlled by lifting and lowering the crucible.

### EXAMPLES

SiC single crystals were produced under the conditions listed in TABLE 1, in the respective rows of Inventive Examples 1 to 3 and Comparative Examples 1 and 2.

TABLE 1

| | Thickness | Amount of | Amount of | | | | |
|---|---|---|---|---|---|---|---|
| | after | Liquid Surface | Crucible | | Internal | | |
| | Growth | Lowering | Lifting | Seed Shaft | Lid | ΔH1 | Evaluation |
| Inventive | 8.8 mm | 6.9 mm | 7.3 mm | 8.7 mm | Fixed | 0.4 mm | G |
| Example 1 | | | | | Position | | |
| Inventive | 6.5 mm | 4.9 mm | 5.0 mm | 6.3 mm | Fixed | 0.1 mm | G |
| Example 2 | | | | | Position | | |
| Inventive | 7.3 mm | 6.9 mm | 0 | 0.4 mm | 7.0 mm | 0.1 mm | G |
| Example 3 | | | | | Lowered | | |
| Comparative | | 7.5 mm | 7.5 mm | 6 mm | 7.5 mm | 7.5 mm | NA |
| Example 1 | | | | | Lifted | | |
| Comparative | | 9.9 mm | 9.9 mm | 9.7 mm | 9.7 mm | 9.7 mm | NA |
| Example 2 | | | | | Lifted | | |

### Inventive Example 1

The composition of the material for Si—C solution was, at atom ratio, Si:Cr=0.6=0.4. The temperature of the portion of the Si—C solution in vicinity to the seed crystal (crystal growth temperature) was 1900° C. The temperature gradient in the portion in vicinity to the seed crystal was 15° C./cm. What was used as the seed crystal was a SiC single crystal of the 4H polytype, and the lower surface (crystal growth surface) thereof was the (000-1) plane. The height of the meniscus at the start of the crystal growth was 0.5 mm.

A production apparatus having the same structure as that of the production apparatus 100 shown in FIG. 1 was used for the production. In Inventive Example 1, the crucible 7 was lifted in accordance with the lowering of the liquid surface 80 while the vertical position of the internal lid 60 was fixed during the growth step such that the amount of variation ΔH1 could be kept not more than the reference value Ref1=0.5 mm.

Specifically, after the lapse of five hours from the start of the crystal growth, the seed shaft 41 started to be lifted. During the growth step, the seed shaft 41 was lifted at a rate of 0.158 mm/hr. The crucible 7 was lifted at a ratio of 0.133 mm/hr. The crystal growth time was 60 hours.

From the start of the crystal growth to the end of the crystal growth, the liquid surface lowered by 6.9 mm, and the crucible 7 was lifted by 7.3 mm. The seed shaft 41 was lifted by 8.7 mm. Accordingly, the amount of variation ΔH1 was 0.4 mm. The thickness of the produced SiC single crystal was 8.8 mm.

### Inventive Example 2

The production apparatus, the seed crystal, the crystal growth temperature and the temperature gradient in Inventive Example 2 were the same as those in Inventive Example 1. The composition of the material for Si—C solution was, at atom ratio, Si:Ti=0.77:0.23. Then, the crucible 7 was lifted in accordance with the lowering of the liquid surface 80 while the vertical position of the internal lid 60 was fixed during the growth step such that the amount of variation ΔH1 could be kept not more than the reference value Ref1=0.5 mm.

Specifically, after the lapse of five hours from the start of the crystal growth, the seed shaft 41 started to be lifted. During the growth step, the seed shaft 41 was lifted at a rate of 0.115 mm/hr. The crucible 7 was lifted at a ratio of 0.09 mm/hr. The crystal growth time was 60 hours.

From the start of the crystal growth to the end of the crystal growth, the liquid surface lowered by 4.9 mm, and the crucible 7 was lifted by 5.0 mm. The seed shaft 41 was lifted by 6.3 mm. Accordingly, the amount of variation ΔH1 was 0.1 mm. The thickness of the produced SiC single crystal was 6.5 mm.

### Inventive Example 31

The production apparatus, the seed crystal, the material for Si—C solution, the crystal growth temperature and the temperature gradient in Inventive Example 3 were the same as those in Inventive Example 1. Unlike in the cases of Inventive Example 1 and Inventive Example 2, the internal lid 60 was lowered in accordance with the lowering of the liquid surface 80 while the vertical position of the crucible 7 was fixed during the growth step such that the amount of variation ΔH1 could be kept not more than the reference value Ref1=0.5 mm.

Specifically, after the lapse of five hours from the start of the crystal growth, the seed shaft 41 started to be lifted. During the growth step, the seed shaft 41 was lifted at a rate of 0.007 mm/hr. The internal lid 60 was lowered at a ratio of 0.127 mm/hr. The crystal growth time was 60 hours.

From the start of the crystal growth to the end of the crystal growth, the liquid surface lowered by 6.9 mm, and the seed shaft 41 was lifted by 0.4 mm. The internal lid 60 was lowered by 7.0 mm. Accordingly, the amount of variation ΔH1 was 0.1 mm. The thickness of the produced SiC single crystal was 7.3 mm.

### Comparative Example 11

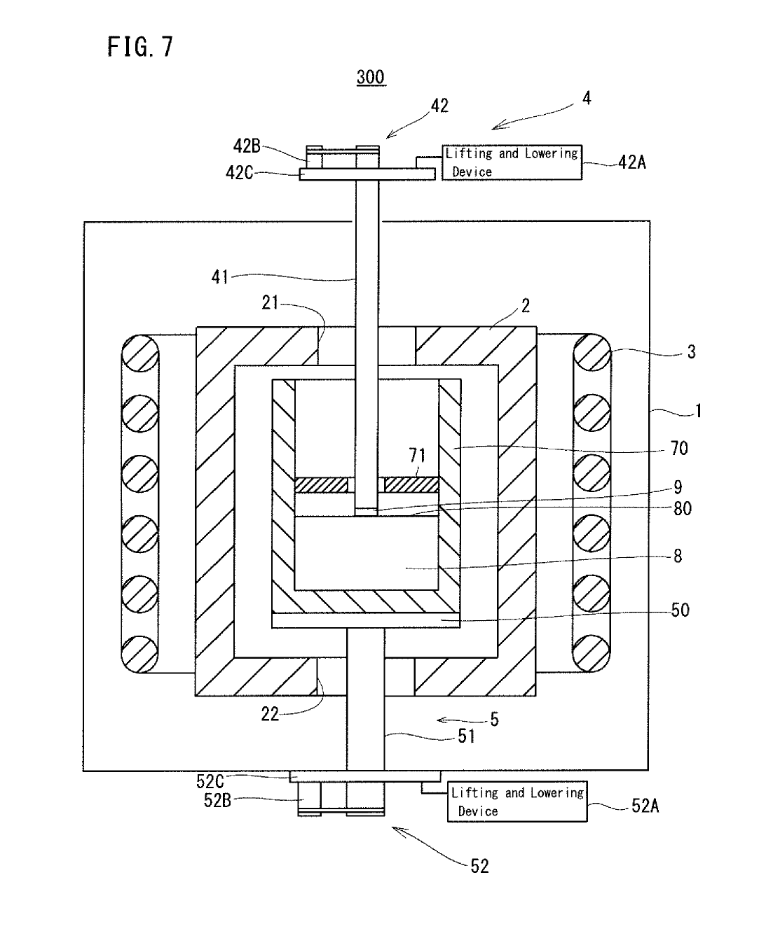

In Comparative Example 1, the production apparatus 300 shown in FIG. 7 was used. As compared with the production apparatus 100, the production apparatus 300 did not comprise the internal lid drive mechanism 6. Further, a crucible 70 was used instead of the crucible 7. As compared with the crucible 7, the crucible 70 included an internal lid 71 fixed to the inner surface thereof. There were no other differences in structure between the crucible 7 and the crucible 70. The seed crystal, the material for Si—C solution, the crystal growth temperature and the temperature gradient in Comparative Example 1 were the same as those in Inventive Example 1.

A SiC single crystal was produced while the crucible and the seed shaft were lifted. The meniscus at the start of the crystal growth was 0.5 mm. The crystal growth time was 60 hours.

After the lapse of five hours from the start of the crystal growth, the seed shaft 41 started to be lifted. During the growth step, the seed shaft 41 was lifted at a rate of 0.11 mm/hr. The crucible 70 was lifted at a ratio of 0.136 mm/hr. The crystal growth time was 60 hours.

From the start of the crystal growth to the end of the crystal growth, the liquid surface lowered by 7.5 mm, and the crucible 7 was lifted by 7.5 mm. The seed shaft 41 was lifted by 6.0 mm. Since the internal lid 71 moved up along with the crucible 70, the internal lid 71 was lifted by 7.5 mm.

### Comparative Example 2

As in Comparative Example 1, the production apparatus 300 shown in FIG. 7 was used in Comparative Example 2. As in Comparative Example 1, a SiC single crystal was produced while the crucible and the seed shaft were lifted. The seed crystal, the material for Si—C solution and the temperature gradient in Comparative example 2 were the same as those in Inventive Example 1. The crystal growth temperature was 1950° C. The meniscus at the start of the crystal growth was 0.5 mm. The crystal growth time was 65 hours.

After the lapse of five hours from the start of the crystal growth, the seed shaft 41 started to be lifted. During the growth step, the seed shaft 41 was lifted at a rate of 0.152 mm/hr. The crucible was lifted at a ratio of 0.149 mm/hr. The crystal growth time was 65 hours.

From the start of the crystal growth to the end of the crystal growth, the liquid surface lowered by 9.9 mm, and the crucible was lifted by 9.9 mm. The seed shaft 41 was lifted by 9.7 mm. Since the internal lid 71 moved up along with the crucible 70, the internal lid 71 was lifted by 9.7 mm.

### [Evaluation Method]

With regard to each of Inventive Examples 1 to 3 and Comparative Examples 1 and 2 produced by the above-described methods, after the elapse of the crystal growth time, the seed shaft 41 was lifted, thereby separating the grown SiC single crystal from the Si—C solution. Thereafter, the inside of the chamber was cooled slowly to room temperature.

After the slow cooling, the bottom surface (crystal growth surface) of the SiC single crystal was observed by optical microscope. If the crystal growth surface is flat, it shows that the temperature of the vicinity portion of the Si—C solution and the temperature of the peripheral portion of the Si—C solution changed little during the growth step. It is a case where the single crystal was easy to grow, and the case was evaluated as good. If the periphery of the crystal growth surface protrudes as compared with the central portion (that is, if the periphery of the crystal growth surface has grown preferentially), it shows that the temperature of the vicinity portion of the Si—C solution and the temperature of the peripheral portion of the Si—C solution changed greatly during the growth step. It is a case where the single crystal was hard to grow, and the case was evaluated as not acceptable.

TABLE 1 shows the results. In TABLE 1, in the column of Evaluation, “G (good)” indicates that the crystal growth surface was flat, and “NA (not acceptable)” indicates that the periphery of the crystal growth surface protruded as compared with the central portion.

With reference to TABLE 1, in Inventive Examples 1 to 3, the crystal growth surface was flat, and these examples were good. This is conceivably because the variation in the distance between the internal lid and the liquid surface was not more than the reference value Ref1. On the other hand, in Comparative Examples 1 and 2, the periphery of the crystal growth surface protruded as compared with the central portion. This is conceivably because the distance between the internal lid and the liquid surface became too large as time passed during the growth step, thereby causing temperature changes of the Si—C solution 8.

Some embodiments of the present invention have been described. However, the above-described embodiments are merely examples to show how to carry out the present invention. Therefore, it is possible to modify the above embodiments as appropriate without departing from the gist and the scope thereof.

1. A method for producing a SiC single crystal by a solution growth process, the method comprising:
a preparation step of preparing a production apparatus comprising a crucible containing material for Si—C solution, a seed shaft including a bottom edge which a seed crystal is attached to, and an internal lid having, in a center, a through hole which the seed shaft passes through and capable of being located inside the crucible;
a formation step of heating the material in the crucible to form the Si—C solution;
a growth step of bringing the seed crystal into contact with the Si—C solution to produce the Si—C single crystal on the seed crystal; and
an internal lid adjustment step of vertically moving one of the internal lid and the crucible relative to the other during the growth step to keep an amount of variation in distance between the internal lid and the Si—C solution within a first reference range.

2. The method according to claim 1, wherein
in the internal lid adjustment step, the amount of variation in the vertical distance between the internal lid and the Si—C solution is adjusted based on an amount of change in vertical position of a liquid surface of the Si—C solution per unit time during the growth step.

3. The method according to claim 1 or 2, wherein:
the production apparatus further comprises a high-frequency heating coil disposed around the crucible; and
the method further comprises a coil adjustment step of vertically moving one of the high-frequency heating coil and the crucible relative to the other such that an amount of variation in positions of the high-frequency heating coil and the Si—C solution relative to each other is within a second reference range.

4. The method according to claim 3, wherein
in the coil adjustment step, the amount of variation in positions of the high-frequency heating coil and the Si—C solution relative to each other is adjusted based on an amount of change in vertical position of a liquid surface of the Si—C solution per unit time during the growth step.

5. An apparatus for producing a SiC single crystal by a solution growth process, the apparatus comprising:
a chamber capable of housing a crucible capable of containing a Si—C solution;
a base capable of supporting the crucible;
a seed shaft including a bottom edge which a seed crystal is attachable to; and
an internal lid having, in a center, a through hole which the seed shaft passes through and capable of being located inside the crucible, above a liquid surface of the Si—C solution; wherein
one of the base and the internal lid is vertically movable relative to the other.

6. The apparatus according to claim 5, further comprising
a cylindrical high-frequency heating coil; wherein
the crucible is capable of being located inside the high-frequency heating coil; and
one of the base and the high-frequency heating coil is vertically movable relative to the other.

7. The apparatus according to claim 5, further comprising
an internal lid lifting mechanism configured to lift and lower the internal lid separately from the seed shaft and the base.

8. The apparatus according to claim 5, further comprising
a crucible lifting mechanism on top of which the crucible can be placed, the crucible lifting mechanism configured to lift and lower the crucible.

9. The apparatus according to claim 6, further comprising
a coil lifting mechanism configured to lift and lower the high-frequency heating coil.

10. The method according to claim 2, wherein:
the production apparatus further comprises a high-frequency heating coil disposed around the crucible; and
the method further comprises a coil adjustment step of vertically moving one of the high-frequency heating coil and the crucible relative to the other such that an amount of variation in positions of the high-frequency heating coil and the Si—C solution relative to each other is within a second reference range.

11. The method according to claim 10, wherein
in the coil adjustment step, the amount of variation in positions of the high-frequency heating coil and the Si—C solution relative to each other is adjusted based on an amount of change in vertical position of a liquid surface of the Si—C solution per unit time during the growth step.

12. The apparatus according to claim 6, further comprising
an internal lid lifting mechanism configured to lift and lower the internal lid separately from the seed shaft and the base.

13. The apparatus according to claim 6, further comprising
a crucible lifting mechanism on top of which the crucible can be placed, the crucible lifting mechanism configured to lift and lower the crucible.

14. The apparatus according to claim 7, further comprising
a crucible lifting mechanism on top of which the crucible can be placed, the crucible lifting mechanism configured to lift and lower the crucible.

15. The apparatus according to claim 12, further comprising
a crucible lifting mechanism on top of which the crucible can be placed, the crucible lifting mechanism configured to lift and lower the crucible.
